(19) United States
(12) Patent Application Publication
(10) Pub. No.: US 2016/0056268 A1
(43) Pub. Date: Feb. 25, 2016

(54) METHOD FOR FABRICATING SEMICONDUCTOR DEVICE IMPROVING THE PROCESS SPEED

(71) Applicant: Samsung Electronics Co., Ltd., Suwon-si (KR)

(72) Inventors: Hock-Chun CHIN, Hwaseong-si (KR); Nak-Jin SON, Suwon-si (KR); Sang-Hyeon LEE, Seongnam-si (KR)

(21) Appl. No.: 14/638,864

(22) Filed: Mar. 4, 2015

(30) Foreign Application Priority Data
Aug. 21, 2014 (KR) 10-2014-0109095

(51) Int. Cl. H01L 29/66; H01L 21/265

(52) U.S. Cl. CPC H01L 29/66795; H01L 21/265

(57) ABSTRACT

A method for fabricating a semiconductor device improving the process speed is provided. The method includes forming a fin on a substrate, forming a gate electrode on the fin, first ion-implanting a first impurity to amorphize a region including portions of the fin positioned at opposite sides of the gate electrode, forming a stress inducing layer on the substrate and the fin, and annealing the substrate to recrystallize the amorphized region, wherein after the forming of the fin and before the annealing, the method further includes second ion-implanting a second impurity different from the first impurity into the fin.

### CROSS-REFERENCE TO RELATED APPLICATION

This application claims priority from Korean Patent Application No. 10-2014-0109095 filed on Aug. 21, 2014 in the Korean Intellectual Property Office, and all the benefits accruing therefrom under 35 U.S.C. 119, the contents of which in its entirety are herein incorporated by reference.

### BACKGROUND

1. Field of the Inventive Concepts

The present inventive concepts relates to a method for fabricating a semiconductor device improving the process speed.

2. Description of the Related Art

In order to improve performance of a metal oxide semiconductor (MOS) transistor, conductivity of a channel region of the MOS transistor may be increased. For example, the charge carrier mobility may be increased by altering a lattice structure of the channel region, thereby increasing the conductivity of the channel region of the MOS transistor.

The lattice structure of the channel region may be altered by generating a stressor near the channel region. Accordingly, the charge carrier mobility may be increased. In detail, in order to generate the stressor, a stress memorization technique (SMT) may be employed. According to the SMT, an amorphized region is formed to be adjacent to the channel region of the MOS transistor, followed by annealing in a state in which a stress inducing layer is positioned on the MOS transistor, thereby recrystallizing the amorphized region. Since the amorphized region is recrystallized while being affected by the stress applied from the stress inducing layer, transformed crystals may be generated. Even if the stress inducing layer positioned on the MOS transistor is removed, the transformed crystals maintain their transformed states, so that the stress is memorized in the transformed crystals. As the result, the transformed crystals act as stressors, thereby affecting the lattice structure of the channel region and ultimately increasing the charge carrier mobility.

Meanwhile, when the SMT is applied to a fin type field effect transistor (FinFET) or a nanowire transistor, the process speed is considerably reduced, which is because a fin or a nanowire undergoes very slow recrystallization due to surface proximity.

### SUMMARY

The present inventive concepts provides a method for fabricating a semiconductor device improving the process speed.

According to an aspect of the present inventive concepts, there is provided a method for fabricating a semiconductor device, the method including forming a fin on a substrate, forming a gate electrode on the fin, first ion-implanting a first impurity to amorphize a region including portions of the fin positioned at opposite sides of the gate electrode, forming a stress inducing layer on the substrate and the fin, and annealing the substrate to recrystallize the amorphized region, wherein after the forming of the fin and before the annealing, the method further comprises second ion-implanting a second impurity different from the first impurity into the fin.

According to another aspect of the present inventive concepts, there is provided a method for fabricating a semiconductor device, the method including forming a fin on a substrate, first ion-implanting first electrically active impurities (EAIs) into the fin, forming a gate electrode on the fin, performing a pre-amorphization implantation (PAI) process to amorphize a region including portions of the fin positioned at opposite sides of the gate electrode, forming a stress inducing layer on the substrate and the fin, and annealing the substrate to recrystallize the amorphized region.

According to still another aspect of the present inventive concepts, there is provided a method for fabricating a semiconductor device, the method comprising forming a gate electrode on a substrate, performing a pre-amorphization implantation (PAI) process to amorphize portions of source/drain regions positioned at opposite sides of the gate electrode, forming a stress inducing layer on the substrate, and annealing the substrate to recrystallize the amorphized region, wherein before the annealing, ion-implanting boron (B) into at least portions of the source/drain regions.

### BRIEF DESCRIPTION OF THE DRAWINGS

The above and other features and advantages of the present inventive concepts will become more apparent by describing in detail example embodiments thereof with reference to the attached drawings in which:

FIGS. 1 to 13 illustrate intermediate process steps in a method for fabricating a semiconductor device according to a first embodiment of the present inventive concepts;

FIG. 14 illustrates intermediate process steps in a method for fabricating a semiconductor device according to a second embodiment of the present inventive concepts;

FIG. 15 illustrates intermediate process steps in a method for fabricating a semiconductor device according to a third embodiment of the present inventive concepts;

FIG. 16 illustrates intermediate process steps in a method for fabricating a semiconductor device according to a fourth embodiment of the present inventive concepts;

FIG. 17 is a schematic block diagram illustrating a memory card including semiconductor devices fabricated by methods for fabricating a semiconductor device according to some embodiments of the present inventive concepts;

FIG. 18 is a schematic block diagram illustrating an information processing system using a semiconductor device fabricated by methods for fabricating a semiconductor device according to some embodiments of the present inventive concepts;

FIG. 19 is a block diagram of an electronic device including a semiconductor device fabricated by methods for fabricating a semiconductor device according to some embodiments of the present inventive concepts.

### DETAILED DESCRIPTION OF THE EMBODIMENTS

Advantages and features of the present inventive concepts and methods of accomplishing the same may be understood more readily by reference to the following detailed description of example embodiments and the accompanying drawings. The present inventive concepts may, however, be embodied in many different forms and should not be construed as being limited to the embodiments set forth herein. Rather, these embodiments are provided so that this disclosure will be thorough and complete and will fully convey the concepts of the inventive concepts to those skilled in the art, and the present inventive concepts will only be defined by the appended claims. Like reference numerals refer to like elements throughout the specification.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which the present inventive concepts belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

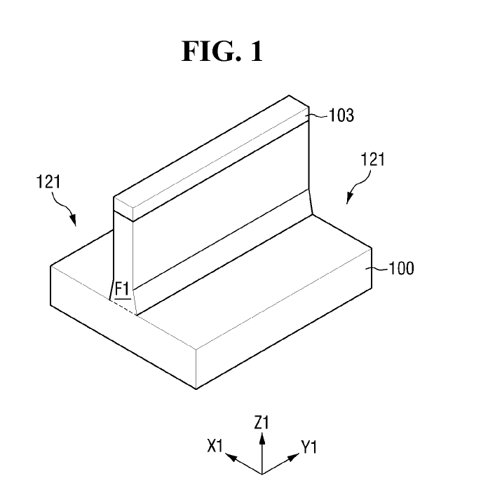

Hereinafter, a method for fabricating a semiconductor device according to a first embodiment of the present inventive concepts will be described with reference to FIGS. 1 to 13.

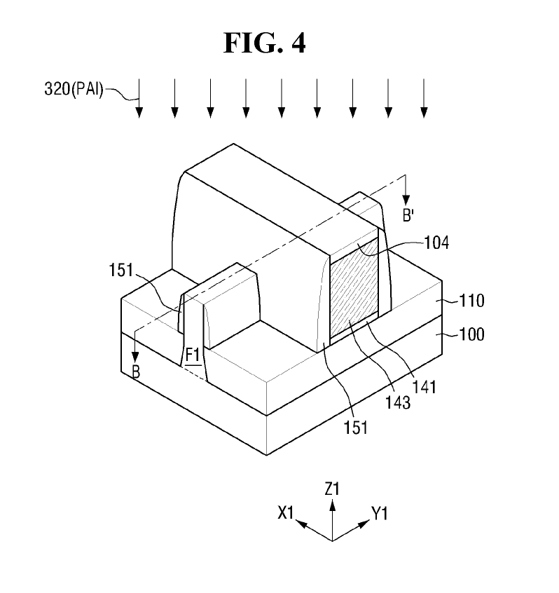

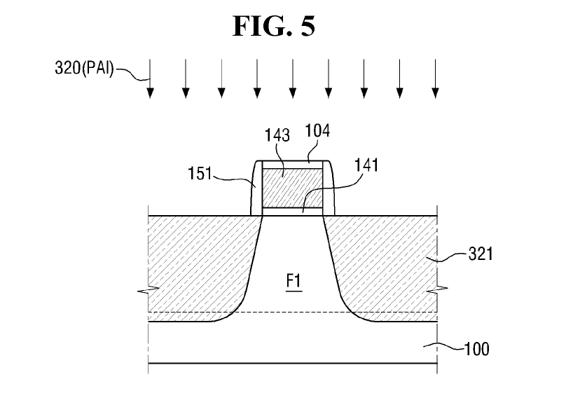

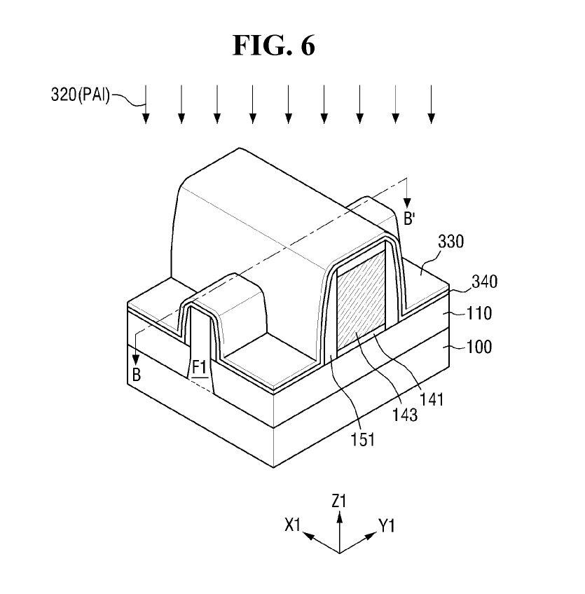

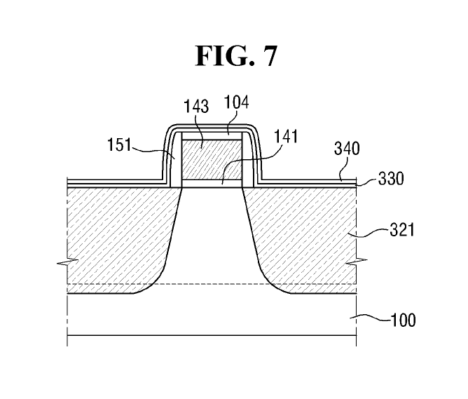

FIGS. 1 to 13 illustrate intermediate process steps in a method for fabricating a semiconductor device according to a first embodiment of the present inventive concepts. Specifically, FIGS. 5 and 7 are cross-sectional views taken along the line B-B′ of FIGS. 4 and 6.

The method for fabricating the semiconductor device according to the first embodiment of the present inventive concepts may be a method for fabricating an NMOS transistor. Therefore, while a process for the method for fabricating the semiconductor device according to the first embodiment of the present inventive concepts is performed, a region other than an NMOS region (e.g., a PMOS region) may be covered by a mask.

Referring to FIG. 1, a fin F1 is formed on a substrate 100.

In detail, a mask pattern 103 is formed on the substrate 100, followed by etching, thereby forming the fin F1. The fin F1 may extend in a second direction Y1. A trench 121 is formed in proximity of the fin F1. The mask pattern 103 may be made of a material including at least one of silicon oxide, silicon nitride, and silicon oxynitride.

The substrate 100 may be bulk silicon or a silicon-on-insulator (SOI). Alternatively, the substrate 100 may be a silicon substrate, or a substrate made of other materials selected from the group consisting of, for example, germanium, silicon germanium, indium antimonide, lead telluride compound, indium arsenide, indium phosphide, gallium arsenide, and gallium antimonide, but aspects of the present inventive concepts are not limited thereto.

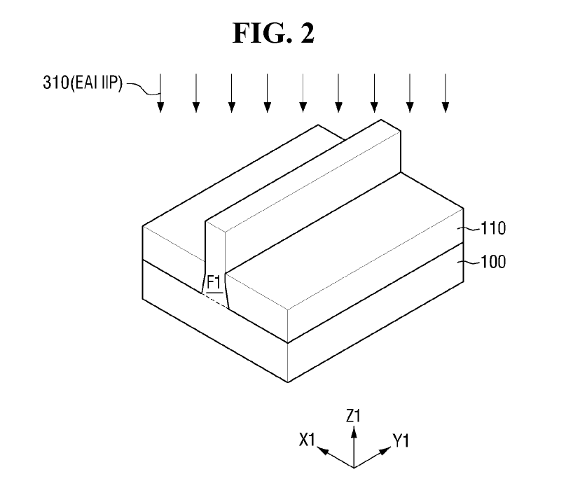

Referring to FIG. 2, an isolation layer 110 filling the trench 121 is formed. The isolation layer 110 may be made of a material including at least one of silicon oxide, silicon nitride, and silicon oxynitride.

Next, a top portion of the isolation layer 110 is recessed to expose a top portion of the fin F1. The recessing may include a selective etching process. The mask pattern 103 may be removed before the forming of the isolation layer 110 or after the recessing.

Alternatively, a portion of the fin F1 upwardly protruding from the isolation layer 110 may be formed by an epitaxial process. In detail, after the forming of the isolation layer 110, a portion of the fin F1 may be formed by an epitaxial process using a top surface of the fin F1 exposed by the isolation layer 110 as a seed, without being recessed.

Next, a first impurity, for example, electrically active impurities (EAIs) may be first ion-implanted into the fin F1 (310).

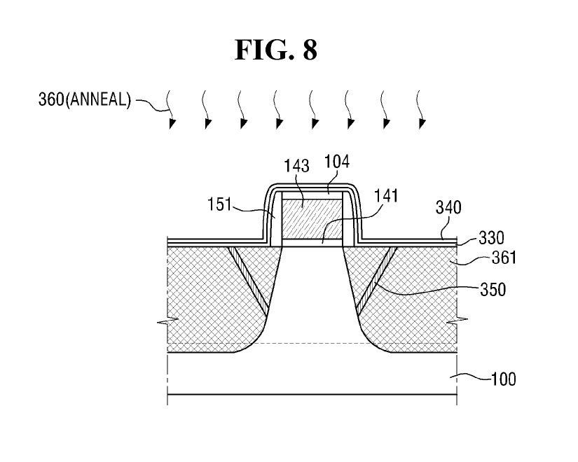

Here, the first impurity may include B, As, P, Sb, Si, Ge or combinations thereof. As will later be described, the first impurity may enhance the recrystallization speed in annealing (see FIG. 8) and may suppress creation of stacking faults (350 of FIG. 8). The first impurity may be different from a second impurity used in a pre-amorphization implantation (PAI) process (see FIGS. 4 and 5). When the first impurity is boron (B), example process conditions may include implantation energy ranging from 10 to 15 KeV and implantation dose ranging from 1E14 to 5E15 atoms/cm².

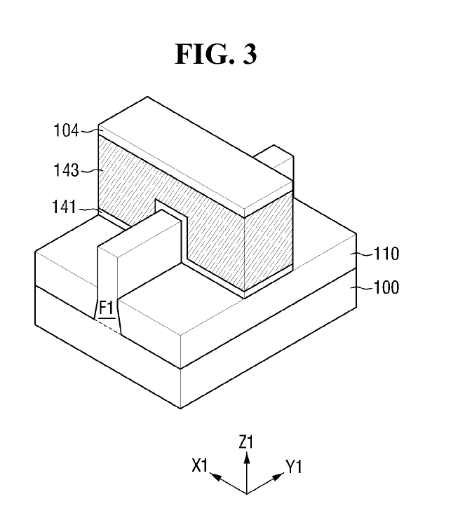

Referring to FIG. 3, an etching process is performed using the mask pattern 104 to form a gate insulation layer 141 and a gate electrode 143 crossing the fin F1 and extending in a first direction X1.

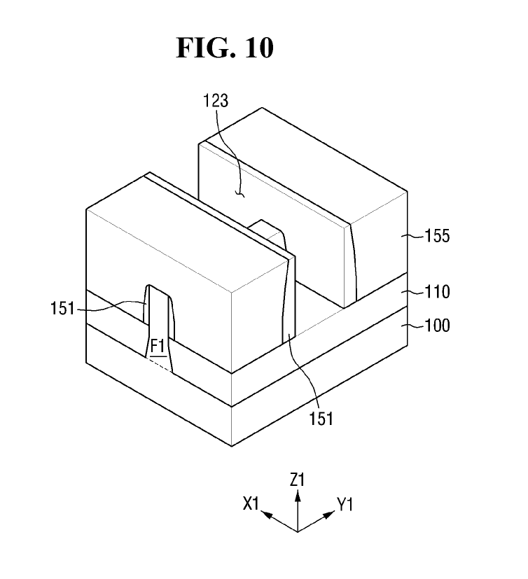

The gate electrode 143 may be a dummy gate electrode and the gate insulation layer 141 may be a dummy gate insulation layer. That is to say, the gate electrode 143 and the gate insulation layer 141 may be removed in a subsequent process (see FIG. 10). For example, the gate insulation layer 141 may be a silicon oxide layer and the gate electrode 143 may be a polysilicon layer.

Referring to FIGS. 4 and 5, spacers 151 are formed on sidewalls of the gate electrode 143 and sidewalls of the fin F1.

For example, the spacers 151 may be formed by forming an insulation layer on the resultant product having the gate electrode 143 and then performing an etch-back process. The spacers 151 may expose a top surface of the mask pattern 104 and the top surface of the fin F1. The spacers 151 may include silicon nitride or silicon oxynitride.

Next, a pre-amorphization implantation (PAI) process is performed to form an amorphized region 321. That is to say, portions of the fin F1 positioned at opposite sides of the gate electrode 143 may be amorphized. In detail, a second impurity is second ion-implanted using the gate electrode 143 and the spacers 151 as masks, thereby forming the amorphized region 321. At least a portion of the amorphized region 321 may be a potential region of a source/drain.

Here, the second impurity may be different from the first impurity. The second impurity may be Ge or Si. However, after the second impurity is second ion-implanted, lateral diffusion may occur. Therefore, the amorphized region 321 may extend to a portion of a channel region.

When the PAI process is performed with high ion-implantation energy of 35 KeV or greater, considerable portions of the channel region may be amorphized due to lateral diffusion. Therefore, in order to reduce or minimize the amorphization of the channel region due to the lateral diffusion during the PAI process, Ge or Si may be ion-implanted with ion-implantation energy in the range of, for example, 10 to 35 KeV.

Referring to FIGS. 6 and 7, a stress inducing layer 340 may be formed on the substrate 100, the fin F1 and the gate electrode 143. In addition, before the forming of the stress inducing layer 340, a buffer layer 330 may be formed.

The buffer layer 330 and the stress inducing layer 340 may be deposited by, for example, atomic layer deposition (ALD) or chemical vapor deposition (CVD), but not limited thereto.

The buffer layer 330 may be conformally formed on the substrate 100, the fin F1 and the spacers 151. The buffer layer 330 may include silicon oxide considerably different from silicon nitride included in the stress inducing layer 340 in view of etching selectivity, but not limited thereto. Since the buffer layer 330 includes silicon oxide, it may be used as an etch stop layer when the stress inducing layer 340 is removed.

In addition, since the buffer layer 330 is formed to cover the substrate 100, and may mitigate or prevent the gate electrode 143 and the spacers 151 from being damaged when the stress inducing layer 340 is removed.

As described above, the semiconductor device according to the first embodiment of the present inventive concepts may be an NMOS transistor. Therefore, the stress inducing layer 340 may include a material capable of applying tensile stress to a channel region. The stress inducing layer 340 may include, for example, silicon nitride, but not limited thereto.

Referring to FIG. 8, the substrate 100 is annealed to recrystallize the amorphized region 321 (360).

In detail, the process shown in FIG. 8 may be a solid phase epitaxy (SPE) process. The SPE process may include a low-temperature annealing process. In the SPE process, annealing is performed at a temperature ranging from 450 to 800° C. in an atmosphere with a mixed gas of N₂, H₂, O₂, and so on, thereby crystallizing the amorphized region 321 in a solid phase. The amorphized region 321 may be recrystallized to become a recrystallized region 361. At least a portion of the recrystallized region 361 may become a source/drain of an NMOS transistor in a subsequent process.

Since the method for fabricating the semiconductor device according to the first embodiment of the present inventive concepts employs a stress memorization technique (SMT), the amorphized region 321 may be transformed by the stress inducing layer 340 to then be recrystallized. Therefore, even if the stress inducing layer 340 is removed in a subsequent process, the transformed state of the recrystallized region 361 may be maintained. Accordingly, the recrystallized region 361 may continuously apply tensile stress to the channel region, altering the lattice structure of the channel region, thereby increasing mobility of charge carriers and ultimately improving performance of the semiconductor device.

Since the SPE process is performed under the tensile stress induced by the stress inducing layer 340, crystals tend to grow at different rates according to the crystallographic directions. For example, during the recrystallization of the amorphized region 321, the crystal growth rate may be greater in a <100> crystallographic direction than in a <110> crystallographic direction.

In the method for fabricating the semiconductor device according to the first embodiment of the present inventive concepts, the crystal growth rate is increased by first ion-implanted electrically active impurities (EAIs). In detail, in a case where the first ion-implanted EAIs include boron (B), the crystal growth rate in the <100> crystallographic direction is increased approximately 20.8 times and the crystal growth rate in the <110> crystallographic direction is increased approximately 13.3 times, compared to a case where the first ion-implanting is not performed. In a case where the first ion-implanted EAIs include phosphorus (P), the crystal growth rate in the <100> crystallographic direction is increased approximately 8.0 times and the crystal growth rate in the <110> crystallographic direction is increased approximately 7.2 times, compared to a case where the first ion-implanting is not performed.

Therefore, the crystal growth rate in the <100> crystallographic direction relative to the crystal growth rate in the <110> crystallographic direction (that is, <100>/<110>) is increased approximately 1.56 times when the first ion-implanted EAIs include boron (B) (=20.8/13.3). In addition, the crystal growth rate in the <100> crystallographic direction relative to the crystal growth rate in the <110> crystallographic direction (that is, <100>/<110>) is increased approximately 1.11 times when the first ion-implanted EAIs include phosphorus (P) (=8.0/7.2). Consequently, the solid-phase epitaxy growth rate of a fin or a nanowire may be improved. Therefore, the process speed of the SMT can be improved.

Meanwhile, as described above, the crystal growth rate in the <100> crystallographic direction may be greater than the crystal growth rate in the <110> crystallographic direction. As a result, a point at which crystal growth pinches off can appear, thus creating a stacking fault (350). Here, since the crystal growth rate in the <100> crystallographic direction and the crystal growth rate in the <110> crystallographic direction are both increased, a problem of creation of stacking faults can be overcome.

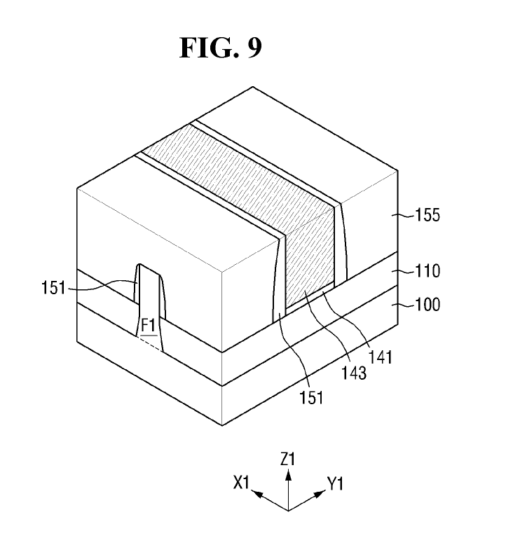

Referring to FIG. 9, the stress inducing layer 340 and the buffer layer 330 are removed. An interlayer insulation layer 155 is formed on the resultant product of FIG. 8. The interlayer insulation layer 155 may be a silicon oxide layer.

Next, the interlayer insulation layer 155 is planarized until a top surface of the gate electrode 143 is exposed. As a result, the mask pattern 104 may be removed and the top surface of the gate electrode 143 may be exposed.

Referring to FIG. 10, the gate insulation layer 141 and the gate electrode 143 are removed. As the gate insulation layer 141 and the gate electrode 143 are removed, a trench 123 exposing the isolation layer 110 is formed.

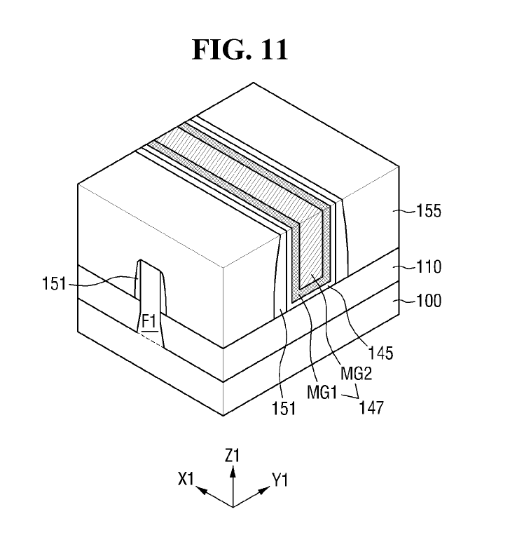

Referring to FIG. 11, a gate insulation layer 145 and a metal gate electrode 147 are formed in the trench 123.

The gate insulation layer 145 may include a high-k material having a higher dielectric constant than the silicon oxide layer. For example, the gate insulation layer 145 may include HfO₂, ZrO₂ or Ta₂O₅. The gate insulation layer 145 may be substantially conformally formed along sidewalls and a bottom surface of the trench 123.

The metal gate electrode 147 may include metal layers MG1 and MG2. As shown, the metal gate electrode 147 may have two or more metal layers MG1 and MG2 stacked one on another. The first metal layer MG1 may function to adjust a work function, and the second metal layer MG2 may function to fill a space formed by the first metal layer MG1. For example, the first metal layer MG1 may include at least one of TiN, TaN, TiC, and TaC. In addition, the second metal layer MG2 may include W or Al. Alternatively, the metal gate electrode 147 may be made of a non-metal material, such as Si, or SiGe.

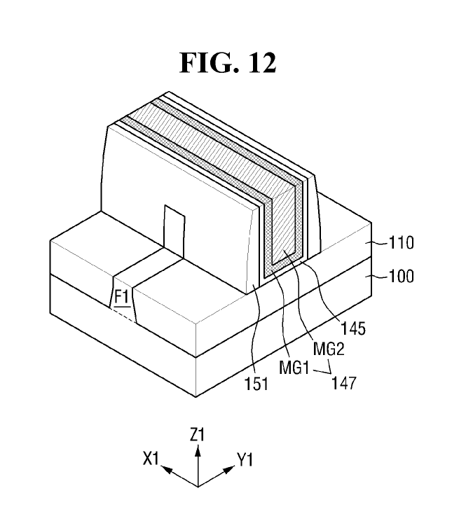

Referring to FIG. 12, a recess 125 is formed in the fin F1 disposed at opposite sides of the metal gate electrode.

The forming of the recess 125 may be performed using dry etching or a combination of wet etching and dry etching.

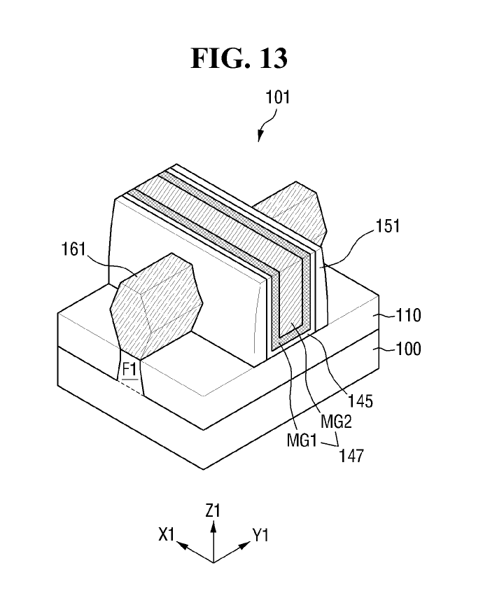

Referring to FIG. 13, a source/drain 161 is formed in the recess. For example, the source/drain 161 may be an elevated source/drain.

In addition, the forming of the source/drain 161 may be performed using an epitaxial process. When necessary, during the epitaxial process, impurities may be in-situ doped. In addition, when necessary, the recess 125 may be filled with a metal, rather than a semiconductor material.

In FIGS. 1 to 13, improvement of the crystal growth rate through ion-implantation of EAIs (e.g., B) in the course of fabricating the FinFET is illustrated, but aspects of the present inventive concepts are not limited thereto. For example, the present inventive concepts may be applied to a planar transistor, instead of the FinFET. That is to say, a gate electrode is formed on a substrate, a pre-amorphization implantation (PAI) process is then performed, a portion of a source/drain region positioned at opposite sides of the gate electrode is amorphized, and a stress inducing layer is formed on the substrate to recrystallize the amorphized region. Here, before the amorphizing, EAIs (e.g., B) may be ion-implanted into at least a portion of the source/drain region.

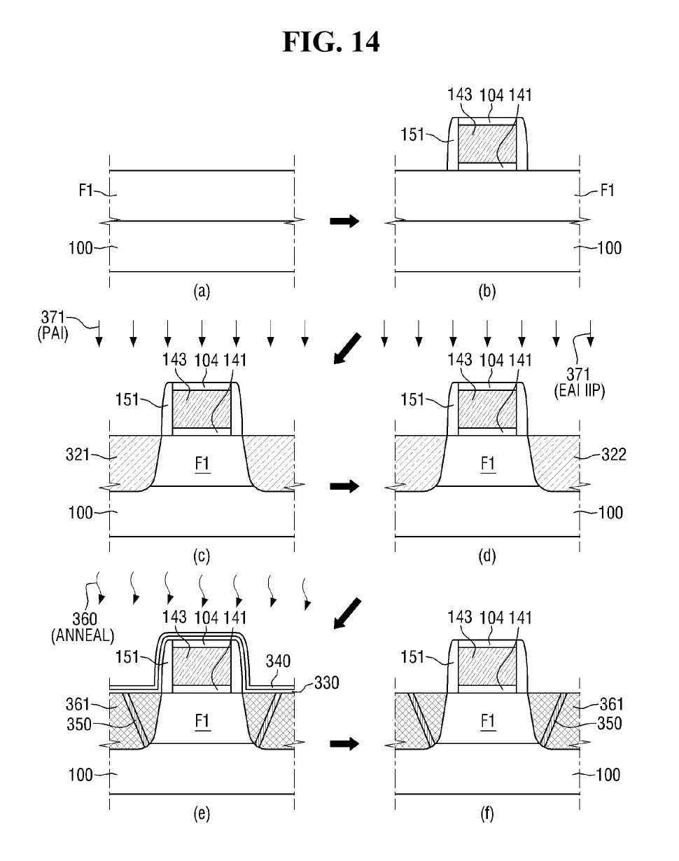

In addition, in FIGS. 1 to 13, the ion-implanting of EAIs (e.g., B) performed after the forming of the fin F1 and before the forming of the gate electrode is illustrated, but aspects of the present inventive concepts are not limited thereto. That is to say, the time of ion-implanting EAIs may be adjusted. Hereinafter, an example of the time of ion-implanting EAIs will be described with reference to FIGS. 14 to 16. For the sake of convenient explanation, the same content as described above with reference to FIGS. 1 to 13 will be omitted.

FIG. 14 illustrates intermediate process steps in a method for fabricating a semiconductor device according to a second embodiment of the present inventive concepts.

Referring to FIG. 14(a), a fin F1 is formed on a substrate 100.

Referring to FIG. 14(b), a gate insulation layer 141 and a gate electrode 143, crossing the fin F1, are formed. Spacers 151 are formed on sidewalls of the gate electrode 143 and sidewalls of the fin F1.

Referring to FIG. 14(c), a pre-amorphization implantation (PAI) process is performed (371) to form an amorphized region 321.

Referring to FIG. 14(d), a first impurity, e.g., electrically active impurities (EAIs), is first ion-implanted into the fin F1 (372).

Referring to FIG. 14(e), a stress inducing layer 340 is formed on the substrate 100, the fin F1 and the gate electrode 143. In addition, before the forming of the stress inducing layer 340, a buffer layer 330 may be formed. The substrate 100 may be annealed to recrystallize the amorphized region 321, thereby forming a recrystallized region 361 (360).

Referring to FIG. 14(f), the stress inducing layer 340 and the buffer layer 330 are removed.

That is to say, the ion-implantating of EAIs may be performed after the PAI process. The first ion-implanting of the EAIs has only to be performed before the recrystallizing.

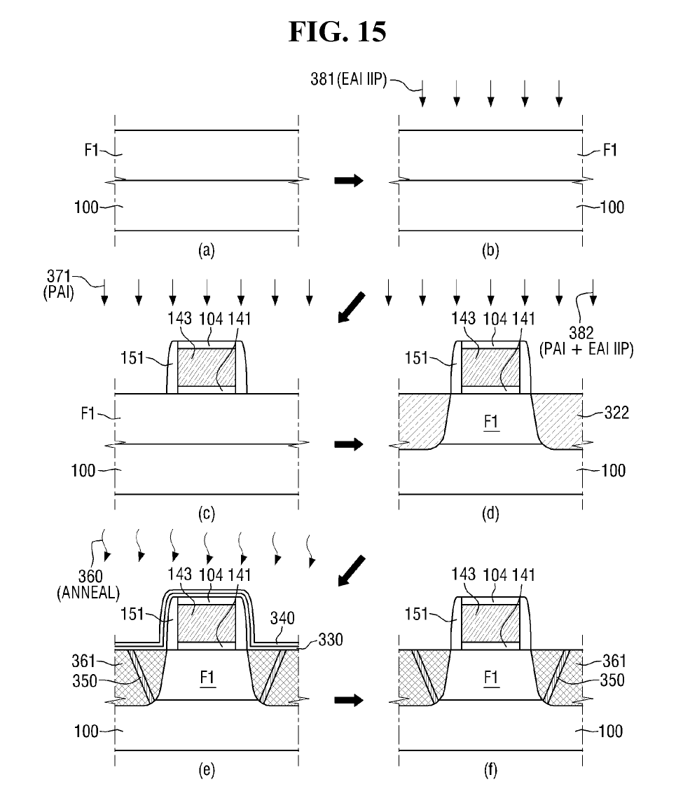

FIG. 15 illustrates intermediate process steps in a method for fabricating a semiconductor device according to a third embodiment of the present inventive concepts.

Referring to FIG. 15(a), a fin F1 is formed on a substrate 100.

Referring to FIG. 15(b), a first impurity, e.g., electrically active impurities (EAIs), is first ion-implanted into the fin F1 (381).

Referring to FIG. 15(c), a gate insulation layer 141 and a gate electrode 143, crossing the fin F1, are formed. Spacers 151 are formed on sidewalls of the gate electrode 143 and sidewalls of the fin F1.

Referring to FIG. 15(d), a pre-amorphization implantation (PAI) process is performed (371) to form an amorphized region 321, and a third impurity, e.g., electrically active impurities (EAIs), is third ion-implanted into the fin F1 (382).

Here, the third impurity may be B, As, P, Sb, Si, Ge or combinations thereof. The third impurity may be different from the impurity used in the PAI process. The third impurity may improve the recrystallizing speed during the annealing (360) and may suppress creation of stacking faults.

In addition, the PAI process and the EAI ion implanting process may be performed at the same time. Alternatively, the EAI ion implanting process may be performed after the PAI process, and the PAI process may be performed after the EAI ion implanting process.

Referring to FIG. 15(e), a stress inducing layer 340 may be formed on the substrate 100, the fin F1 and the gate electrode 143. In addition, before the forming of the stress inducing layer 340, a buffer layer 330 may be formed. The substrate 100 is annealed to recrystallize the amorphized region 321 (360).

Referring to FIG. 15(f), the stress inducing layer 340 and the buffer layer 330 are removed.

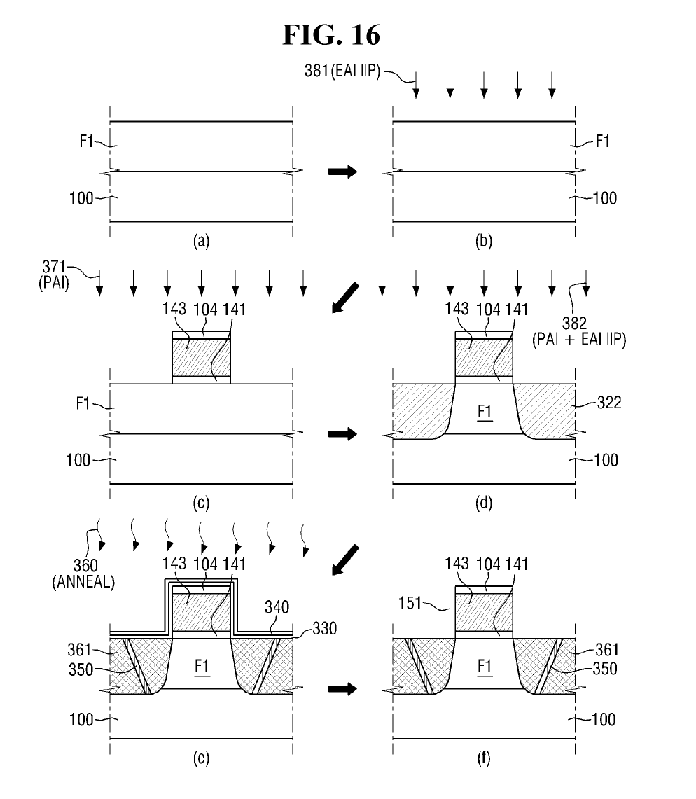

FIG. 16 illustrates intermediate process steps in a method for fabricating a semiconductor device according to a fourth embodiment of the present inventive concepts.

Referring to FIG. 16(a), a fin F1 is formed on a substrate 100.

Referring to FIG. 16(b), a first impurity, e.g., electrically active impurities (EAIs), is first ion-implanted into the fin F1 (391).

Referring to FIG. 16(c), a gate insulation layer 141 and a gate electrode 143, crossing the fin F1, are formed. As shown, spacers 151 are not formed on sidewalls of the gate electrode 143 and sidewalls of the fin F1.

Referring to FIG. 16(d), a pre-amorphization implantation (PAI) process is performed to form an amorphized region 321, and a third impurity, e.g., electrically active impurities (EAIs), is third ion-implanted into the fin F1 (392).

Here, the third impurity may be B, As, P, Sb, Si, Ge or combinations thereof. The third impurity may be different from the impurity used in the PAI process. The third impurity may improve the recrystallizing speed during the annealing (360) and may suppress creation of stacking faults.

The PAI process and the EAI ion implanting process may be performed at the same time. Alternatively, the EAI ion implanting process may be performed after the PAI process, and the PAI process may be performed after the EAI ion implanting process.

Unlike in FIG. 15(d), the PAI process and the EAI ion implanting process may be performed without the forming of the spacers 151. Therefore, the amorphized region 321 may be diffused heavily toward a channel region.

Referring to FIG. 16(e), a stress inducing layer 340 may be formed on the substrate 100, the fin F1 and the gate electrode 143. In addition, before the forming of the stress inducing layer 340, a buffer layer 330 may be formed. The substrate 100 is annealed to recrystallize the amorphized region 321 (360).

Referring to FIG. 16(f), the stress inducing layer 340 and the buffer layer 330 are removed.

In FIGS. 15 and 16, the EAI ion implanting process performed multiple times (e.g., two times). Impurities used in the EAI ion implanting process performed multiple times may be the same with or different from each other.

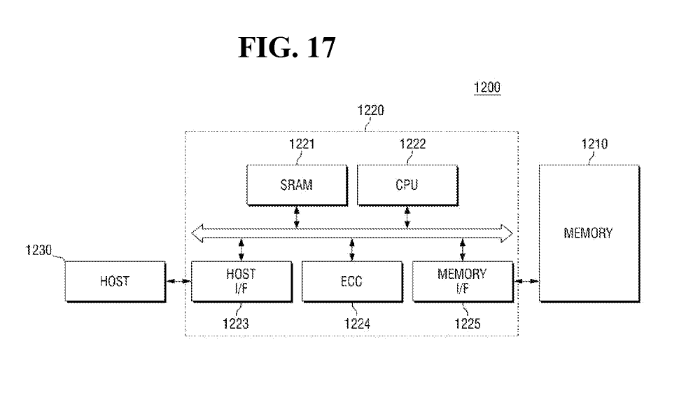

FIG. 17 is a schematic block diagram illustrating a memory card including semiconductor devices fabricated according to some embodiments of the present inventive concepts.

Referring to FIG. 17, a memory 1210 fabricated according to various embodiments of the present inventive concepts may be employed to a memory card 1200. The memory card 1200 includes a memory controller 1220 controlling data exchange between a host 1230 and the memory 1210. A static random access memory (SRAM) 1221 is used as a working memory of a central processing unit 1222. A host interface 1223 includes a data exchange protocol of the host 1230 connected to the memory card 1200. An error correction block 1224 detects and corrects an error included in data read from the memory 1210. A memory interface 1225 interfaces with the memory 1210 according to the present inventive concepts. The central processing unit 1222 performs an overall controlling operation for data exchange of the memory controller 1220.

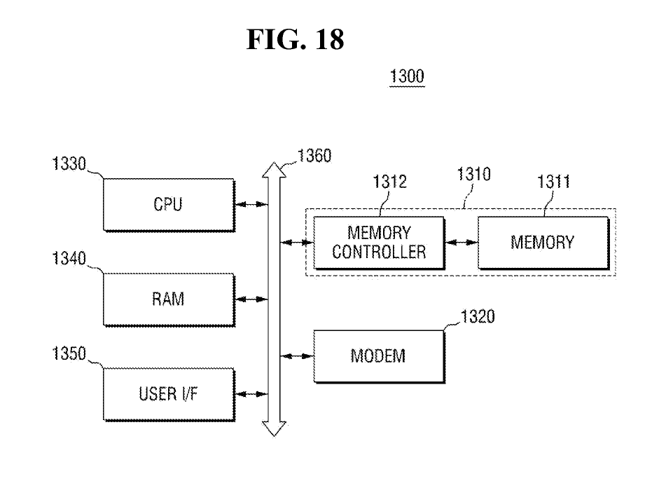

FIG. 18 is a schematic block diagram illustrating an information processing system using a semiconductor device fabricated according to some embodiments of the present inventive concepts.

Referring to FIG. 18, an information processing system 1300 may include a memory system 1310 including semiconductor devices fabricated according to embodiments of the present inventive concepts. The information processing system 1300 in accordance with the present inventive concepts includes the memory system 1310 and a modem 1320, a central processing unit (CPU) 1330, a random access memory (RAM) 1340, and a user interface 1350 that are electrically connected to a system bus 1360, respectively. The memory system 1310 may include a memory 1311 and a memory controller 1312 and may have a configuration that is the same as or substantially similar to the memory card 1200 shown in FIG. 18. The memory system 1310 may store data processed by the central processing unit 1330 or data received from an external device. The information processing system 1300 can be applied to a memory card, a solid-state drive (SSD), a camera image sensor or other various kinds of chip sets. For example, the memory system 1310 may be configured to employ an SSD. In this case, the information processing system 1300 may process store huge amounts of data in a stable, reliable manner.

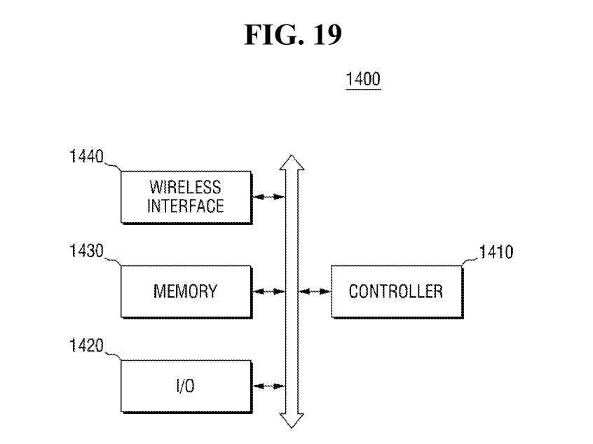

FIG. 19 is a block diagram of an electronic device including a semiconductor device fabricated according to some embodiments of the present inventive concepts.

Referring to FIG. 19, the electronic device 1400 may include a semiconductor device according to various embodiments of the present inventive concepts. The electronic device 1400 may be applied to a wireless communication device (for example, a personal digital assistant (PDA), a notebook computer, a portable computer, a web tablet, a wireless phone, and/or a wireless digital music player) or any type of electronic device capable of transmitting and/or receiving information in a wireless environment.

The electronic device 1400 may include a controller 1410, an input/output device (I/O) 1420, a memory 1430, and a wireless interface 1440. Here, the memory 1430 may include a semiconductor device according to various embodiments of the present inventive concepts. The controller 1410 may include a microprocessor, a digital signal processor, and a processor capable of performing functions similar to these components. The memory 1430 may be used to store commands processed by the controller 1410 (or user data). The wireless interface 1440 may be used to exchange data through a wireless data network. The wireless interface 1440 may include an antenna or a wired/wireless transceiver. For example, the electronic device 1400 may use a third generation communication system protocol, such as CDMA, GSM, NADC, E-TDMA, WCDMA, CDMA2000, or the like.

While the present inventive concepts has been particularly shown and described with reference to example embodiments thereof, it will be understood by those of ordinary skill in the art that various changes in form and details may be made therein without departing from the spirit and scope of the present inventive concepts as defined by the following claims. It is therefore desired that the present embodiments be considered in all respects as illustrative and not restrictive, reference being made to the appended claims rather than the foregoing description to indicate the scope of the inventive concepts.

What is claimed is:

1. A method for fabricating a semiconductor device, the method comprising:
forming a fin on a substrate;
forming a gate electrode on the fin;
first ion-implanting a first impurity to amorphize a region including portions of the fin positioned at opposite sides of the gate electrode;
forming a stress inducing layer on the substrate and the fin; and
annealing the substrate to recrystallize the amorphized region,
wherein after the forming of the fin and before the annealing, the method further comprises second ion-implanting a second impurity different from the first impurity into the fin.

2. The method of claim 1, wherein the second impurity includes electrically active impurities (EAIs).

3. The method of claim 2, wherein the second impurity includes B, As, P, Sb, Si, Ge or combinations thereof.

4. The method of claim 1, wherein the first impurity includes Ge or Si.

5. The method of claim 1, wherein the second ion-implanting is performed after the forming of the fin and before the forming of the gate electrode.

6. The method of claim 5, wherein after the forming of the gate electrode and before the forming of the stress inducing layer, further comprising third ion-implanting a third impurity different from the first impurity into the fin.

7. The method of claim 6, wherein the third impurity includes B, As, P, Sb, Si, Ge or combinations thereof.

8. The method of claim 1, wherein the second ion-implanting is performed after the first ion-implanting and before the forming of the stress inducing layer.

9. The method of claim 1, wherein the first ion-implanting is performed after forming a spacer at sidewalls of the gate electrode.

10. The method of claim 1, after the recrystallizing, further comprising:
removing the stress inducing layer.

11. The method of claim 10, further comprising:
recessing at least portions of the recrystallized region; and
forming an epitaxial layer for a source/drain in the recessed region.

12. The method of claim 11, wherein the gate electrode is a dummy electrode, and after the forming of the epitaxial layer, the gate electrode is removed.

13. A method for fabricating a semiconductor device, the method comprising:
forming a fin on a substrate;
first ion-implanting first electrically active impurities (EAIs) into the fin;
forming a gate electrode on the fin;
performing a pre-amorphization implantation (PAI) process to amorphize a region including portions of the fin positioned at opposite sides of the gate electrode;
forming a stress inducing layer on the substrate and the fin; and
annealing the substrate to recrystallize the amorphized region.

14. The method of claim 13, wherein the first EAIs include B, As, P, Sb, Si, Ge or combinations thereof.

15. The method of claim 13, after the forming of the gate electrode and before the forming of the stress inducing layer, further comprising:
second ion-implanting second EAIs.

16. The method of claim 13, wherein the performing includes ion-implanting Ge or Si into the fin.

17. The method of claim 13, wherein a buffer layer being in direct contact with the fin is positioned between the stress inducing layer and the fin.

18. A method for fabricating a semiconductor device, the method comprising:
forming a gate electrode on a substrate;
performing a pre-amorphization implantation (PAI) process to amorphize portions of source/drain regions positioned at opposite sides of the gate electrode;
forming a stress inducing layer on the substrate; and
annealing the substrate to recrystallize the amorphized region,
wherein before the annealing, ion-implanting boron (B) into at least portions of the source/drain regions.

19. The method of claim 18, wherein the performing includes ion-implanting Ge or Si into the fin.

20. The method of claim 18, after the annealing, further comprising:
removing the stress inducing layer;
recessing at least a portion of the recrystallized region; and
forming an epitaxial layer for a source/drain in the recessed region.
